(19) United States
(12) Patent Application Publication
(10) Pub. No.: US 2025/0185281 A1
(43) Pub. Date: Jun. 5, 2025

(54) SEMICONDUCTOR DEVICE AND METHOD OF MANUFACTURING THE SAME

(71) Applicant: Renesas Electronics Corporation, Tokyo (JP)

(72) Inventors: Makoto KOSHIMIZU, Tokyo (JP); Tohru KAWAI, Tokyo (JP); Yasutaka NAKASHIBA, Tokyo (JP); Tomonari YAMAGUCHI, Tokyo (JP)

(21) Appl. No.: 18/918,201

(22) Filed: Oct. 17, 2024

(30) Foreign Application Priority Data
Dec. 4, 2023 (JP) 2023-204694

(51) Int. Cl. H01L 29/78; H01L 21/762; H01L 29/08; H01L 29/66

(52) U.S. Cl. CPC H10D 30/65; H01L 21/76224; H10D 30/0221; H10D 30/0281; H10D 30/603; H10D 62/157

(57) ABSTRACT

A semiconductor substrate includes a p-type substrate region, an n-type buried layer on the p-type substrate region, and a p-type semiconductor layer on the n-type buried layer. In the semiconductor layer, an n-type semiconductor region is formed so as to surround a transistor in plan view and to reach the n-type buried layer from a main surface of the semiconductor substrate. A DTI region is formed so as to penetrate through the n-type semiconductor region and the n-type buried layer and reach the p-type substrate region.

### CROSS-REFERENCE TO RELATED APPLICATIONS

The disclosure of Japanese Patent Application No. 2023-204694 filed on Dec. 4, 2023 including the specification, drawings and abstract is incorporated herein by reference in its entirety.

### BACKGROUND

The present invention relates to a semiconductor device and a method of manufacturing the same, which are suitably used, for example, for a semiconductor device having a transistor as a power switching element and a method of manufacturing the same.

In a power conversion circuit such as an inverter circuit, a power switching element such as a laterally diffused metal oxide semiconductor field effect transistor (LDMOSFET) is used. The power switching element is formed on a semiconductor substrate. A transistor configuring another circuit may also be formed on the semiconductor substrate on which the power switching element is formed.

There are disclosed techniques listed below.
[Patent Document 1] Japanese Unexamined Patent Application Publication No. 2011-3608
[Patent Document 2] Japanese Unexamined Patent Application Publication No. 2011-66067

FIGS. 19 and 20 of Patent Document 1 disclose a technique in which an array arrangement area ARA of an LDMOS transistor is separated by an n-type isolation region SR. FIGS. 21 and 22 of Patent Document 1 disclose a technique in which the array arrangement area ARA of the LDMOS transistor is separated by a filling insulating film BIS filling an isolation trench TRS.

Patent Document 2 discloses a technique for forming an n-type sinker region NDR in contact with an n-type buried region NBR and a DTI structure that surrounds a formation region of a high breakdown voltage lateral MOS transistor in plan view.

### SUMMARY

In a semiconductor device having a power switching element, it is desired to improve performance thereof as much as possible.

Other objects and novel features will become apparent from the description of the present specification and the accompanying drawings.

According to one embodiment, a semiconductor device includes a semiconductor substrate and a transistor formed on a main surface of the semiconductor substrate. The semiconductor substrate includes a substrate region of a first conductivity type, a buried layer of a second conductivity type formed on the substrate region, and a semiconductor layer of the first conductivity type formed on the buried layer. A first semiconductor region of the second conductivity type is formed in the semiconductor layer so as to surround the transistor in plan view and to reach, from the main surface, the buried layer. The semiconductor device further includes an insulating region that penetrates through the first semiconductor region and the buried layer and reaches the substrate region.

According to one embodiment, the performance of the semiconductor device can be improved. Alternatively, the semiconductor device can be downsized. Alternatively, the performance of the semiconductor device can be improved and the semiconductor device can be downsized.

### BRIEF DESCRIPTION OF THE DRAWINGS

FIG. 1 is a cross-sectional view of a main portion of a semiconductor device according to a first embodiment.

FIG. 2 is a plan view of a main portion of the semiconductor device according to the first embodiment.

FIG. 3 is a plan view of a main portion of the semiconductor device according to the first embodiment.

FIG. 4 is a cross-sectional view of a main portion of the semiconductor device during a manufacturing step according to the first embodiment.

FIG. 5 is a cross-sectional view of a main portion of the semiconductor device during a manufacturing step, following FIG. 4.

FIG. 6 is a cross-sectional view of a main portion of the semiconductor device during a manufacturing step, following FIG. 5.

FIG. 7 is a cross-sectional view of a main portion of the semiconductor device during a manufacturing step, following FIG. 6.

FIG. 8 is a cross-sectional view of a main portion of the semiconductor device during a manufacturing step, following FIG. 7.

FIG. 9 is a cross-sectional view of a main portion of the semiconductor device during a manufacturing step, following FIG. 8.

FIG. 10 is a cross-sectional view of a main portion of the semiconductor device during a manufacturing step, following FIG. 9.

FIG. 11 is a cross-sectional view of a main portion of the semiconductor device during a manufacturing step, following FIG. 10.

FIG. 12 is a cross-sectional view of a main portion of the semiconductor device during a manufacturing step, following FIG. 11.

FIG. 13 is a cross-sectional view of a main portion of the semiconductor device during a manufacturing step, following FIG. 12.

FIG. 14 is a cross-sectional view of a main portion of the semiconductor device during a manufacturing step, following FIG. 13.

FIG. 15 is a circuit diagram illustrating an inverter circuit.

FIG. 16 is a circuit diagram illustrating an inverter circuit.

FIG. 17 is a circuit diagram illustrating an inverter circuit.

FIG. 18 is a cross-sectional view of a main portion of a semiconductor device in an examined example.

FIG. 19 is a cross-sectional view of a main portion of a semiconductor device during a manufacturing step according to a second embodiment.

FIG. 20 is a cross-sectional view of a main portion of a semiconductor device during a manufacturing step according to a third embodiment.

FIG. 21 is a cross-sectional view of a main portion of the semiconductor device during a manufacturing step, following FIG. 20.

FIG. 22 is a cross-sectional view of a main portion of the semiconductor device during a manufacturing step, following FIG. 21.

FIG. 23 is a cross-sectional view of a main portion of the semiconductor device during a manufacturing step, following FIG. 22.

FIG. 24 is a cross-sectional view of a main portion of the semiconductor device during a manufacturing step, following FIG. 23.

FIG. 25 is a cross-sectional view of a main portion of a semiconductor device according to a fourth embodiment.

FIG. 26 is a cross-sectional view of a main portion of a semiconductor package according to a fifth embodiment.

FIG. 27 is a cross-sectional view of a main portion of a semiconductor package according to a sixth embodiment.

### DETAILED DESCRIPTION

In the following embodiments, for convenience, description may be divided into a plurality of sections or embodiments as necessary. However, unless explicitly stated otherwise, they are not irrelevant to each other; rather, one may be a modification, detail, or supplementary description of another, either in part or in whole. Further, in the following embodiments, when referring to the number of elements (including quantity, numerical values, amounts, ranges, etc.), unless explicitly stated otherwise or when it is clearly restricted to a specific number by principle, the reference is not limited to that specific number but may be either more or less than that specific number. Furthermore, in the following embodiments, it goes without saying that the components (including element steps, etc.) are not necessarily essential, except in cases where it is explicitly stated otherwise or where it is clearly considered essential by principle. Similarly, in the following embodiments, when referring to shapes, positional relationships, etc., of components, unless explicitly stated otherwise or where it is clearly considered not to be the case by principle, it is to be understood as including those that are substantially similar to or approximate the described shape, etc. This applies similarly to the above numerical values and ranges.

Hereinafter, the embodiments will be described in detail with reference to the drawings. Note that in all the drawings for describing the embodiments, members with the same functions are denoted by the same reference numerals, and repeated descriptions thereof are omitted. Furthermore, in the following embodiments, descriptions of the same or similar parts are generally not repeated unless specifically necessary.

Also, in the drawings used in the embodiments, hatching may be omitted in cross-sectional views to enhance readability. Or, even in plan views, hatching may be added to enhance readability.

Also, a plan view corresponds to a view from a plane substantially parallel to the main surface or the back surface of a semiconductor substrate SUB. Also, the terms “bottom surface” and “lower surface” are used in a synonymous manner. Also, the height position corresponds to the distance away from the back surface of the semiconductor substrate SUB. Also, the depth position corresponds to the distance away from the main surface of the semiconductor substrate SUB.

Also, in the present application, the Metal Oxide Semiconductor Field Effect Transistor (MOSFET) and the Laterally Diffused Metal Oxide Semiconductor Field Effect Transistors (LDMOSFET) include not only a MOSFET that uses an oxide film as the gate insulating film, but also a MOSFET that uses an insulating film other than an oxide film as the gate insulating film. Also, the LDMOSFET may also be referred to as a High Voltage Metal Oxide Semiconductor Field Effect Transistor (HV-MOSFET) or a Drain Extended Metal Oxide Semiconductor Field Effect Transistor (DEMOSFET).

Also, an n-channel MOSFET can be regarded as an n-type MOSFET, and a p-channel MOSFET can be regarded as a p-type MOSFET. In this case, “n-type” refers to the channel conductivity type being n-type when the MOSFET is ON, and “p-type” refers to the channel conductivity type being p-type when the MOSFET is ON.

### First Embodiment

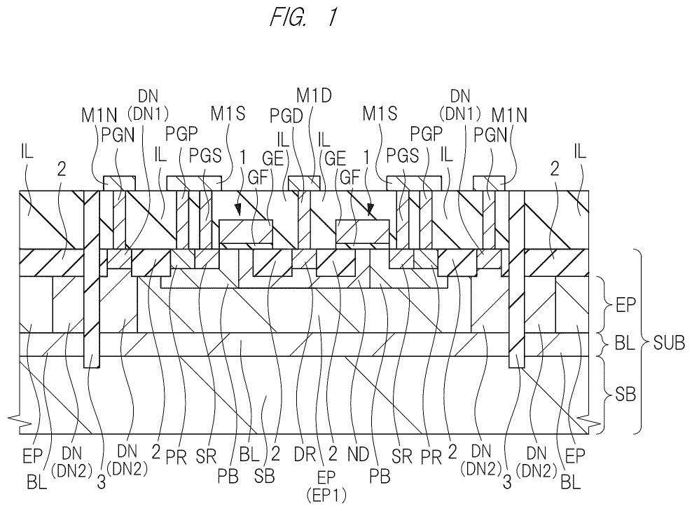

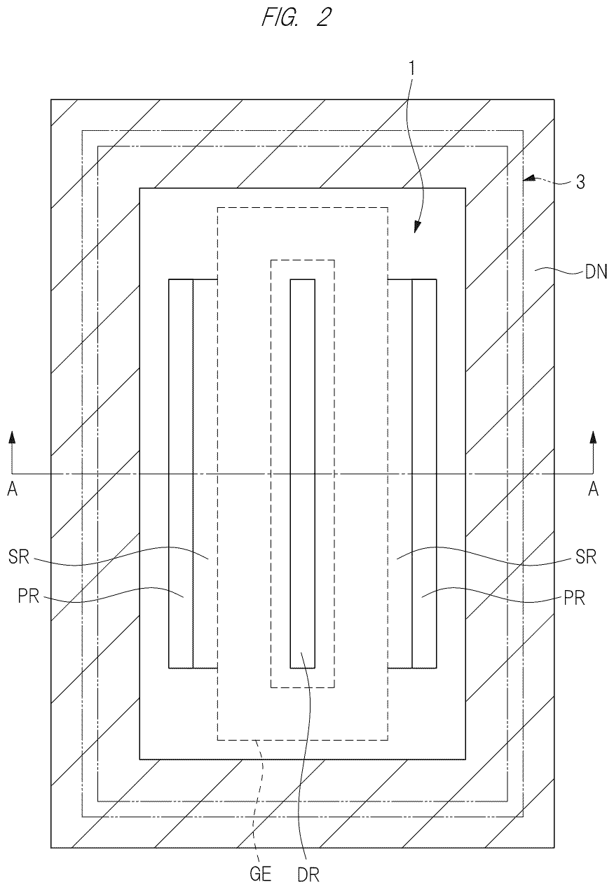

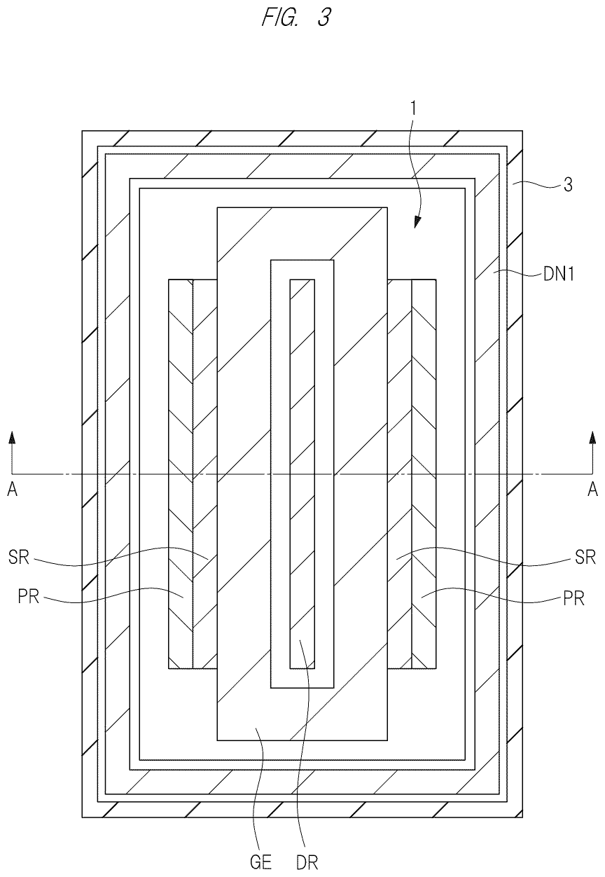

The planar regions illustrated in FIG. 2 and FIG. 3 are the same as each other. Note that in FIG. 2, hatching is applied to an n-type semiconductor region DN, a gate electrode GE is indicated by dashed lines, and a DTI region 3 is indicated by two-dot chain lines. In FIG. 3, hatching is applied to the DTI region 3, an n-type semiconductor region DN1, an n-type source region SR, an n-type drain region DR, and the gate electrode GE. The cross-sectional view along line A-A in FIGS. 2 and 3 corresponds to FIG. 1.

A semiconductor device of the first embodiment includes a power switching element used in a power conversion circuit such as an inverter circuit, and in this case, an LDMOSFET is included as a transistor configuring the power switching element.

As illustrated in FIGS. 1 to 3, the semiconductor device of the first embodiment includes a semiconductor substrate SUB, an STI region 2, the DTI region 3, an LDMOSFET 1 formed on the main surface of the semiconductor substrate SUB, the n-type semiconductor region DN formed in the semiconductor substrate SUB, and an insulating film IL formed on the main surface of the semiconductor substrate SUB.

As illustrated in FIG. 1, the semiconductor substrate SUB includes a p-type substrate region SB, an n-type buried layer BL formed on the p-type substrate region SB, and a p-type semiconductor layer EP formed on the n-type buried layer BL.

The p-type substrate region SB is made of p-type single-crystal silicon, for example, into which p-type impurities such as boron (B) are introduced. The n-type buried layer BL is an n-type semiconductor layer. The thickness of the p-type substrate region SB is substantially uniform. The p-type semiconductor layer EP is made of p-type single-crystal silicon or the like, which is formed on the n-type buried layer BL by epitaxial growth.

The p-type substrate region SB and the n-type buried layer BL configure the main body of the substrate. For example, the n-type buried layer BL is formed by implanting ions of n-type impurities into the upper portion of a p-type substrate body, which is made of p-type single-crystal silicon or the like. In that case, the region under the n-type buried layer BL in the substrate body corresponds to the p-type substrate region SB.

The main surface of the semiconductor substrate SUB corresponds to the main surface of the semiconductor layer EP. The back surface of the semiconductor substrate SUB corresponds to the back surface of the p-type substrate region SB. The main surface of the semiconductor substrate SUB and the back surface of the semiconductor substrate SUB are located on opposite sides of each other.

The Shallow Trench Isolation (STI) region 2 includes an insulating film buried in a trench formed in the semiconductor substrate SUB. The Deep Trench Isolation (DTI) region 3 includes an insulating film buried in a trench formed in the insulating film IL on the semiconductor substrate SUB and in the semiconductor substrate SUB. Both the STI region 2 and the DTI region 3 can be considered as insulating regions.

The depth of the DTI region 3 is greater than the depth of the STI region 2. That is, the depth of the bottom surface of the DTI region 3 is greater than the depth of the bottom surface of the STI region 2. The DTI region 3 penetrates through the insulating film IL, the STI region 2, the semiconductor layer EP, and the n-type buried layer BL, and reaches the p-type substrate region SB. The bottom surface of the DTI region 3 is deeper than the bottom surface of the n-type buried layer BL and is located in the thickness of the p-type substrate region SB. The bottom surface of the STI region 2 is shallower than the upper surface of the n-type buried layer BL and is located in the thickness of the semiconductor layer EP.

The n-type semiconductor region DN is formed in the semiconductor substrate SUB to reach, from the main surface of the semiconductor substrate SUB, the n-type buried layer BL. The n-type semiconductor region DN is formed in the semiconductor layer EP, the bottom surface of the n-type semiconductor region DN is in contact with the upper surface of the n-type buried layer BL, and the upper surface of the n-type semiconductor region DN reaches the main surface of the semiconductor substrate SUB.

The n-type semiconductor region DN includes the n-type semiconductor region DN1 and an n-type semiconductor region DN2. The n-type impurity concentration of the n-type semiconductor region DN1 is higher than the n-type impurity concentration of the n-type semiconductor region DN2. The n-type semiconductor region DN1 is formed in the upper portion of the n-type semiconductor region DN, is in contact with the main surface of the semiconductor substrate SUB, and is formed from the main surface of the semiconductor substrate SUB to a predetermined depth. The n-type semiconductor region DN2 is located under the STI region 2 and the n-type semiconductor region DN1, and is in contact with the n-type semiconductor region DN1. The bottom surface of the n-type semiconductor region DN2 configures the bottom surface of the n-type semiconductor region DN and is in contact with the upper surface of the n-type buried layer BL. The n-type semiconductor region DN1 is electrically connected to the n-type buried layer BL via the n-type semiconductor region DN2.

In plan view, the n-type semiconductor region DN is formed in the semiconductor layer EP so as to surround the LDMOSFET 1. In plan view, the n-type semiconductor region DN has a frame-like planar shape. In plan view, the semiconductor layer EP surrounded by the n-type semiconductor region DN is referred to as a semiconductor layer EP1. In plan view, the semiconductor layer EP1 is surrounded by the n-type semiconductor region DN.

The DTI region 3 is formed so as to penetrate through the n-type semiconductor region DN. The DTI region 3 penetrates through the insulating film IL, the STI region 2, the n-type semiconductor region DN, and the n-type buried layer BL, and reaches the p-type substrate region SB. The side surfaces of the DTI region 3 are in contact with the insulating film IL, the STI region 2, the n-type semiconductor region DN, the n-type buried layer BL, and the p-type substrate region SB, and the bottom surface of the DTI region 3 is in contact with the p-type substrate region SB.

In plan view, the n-type semiconductor region DN surrounds the LDMOSFET 1; therefore, the DTI region 3, which penetrates through the n-type semiconductor region DN, also surrounds the LDMOSFET 1 in plan view. Reflecting that the n-type semiconductor region DN has a frame-like planar shape in plan view, the DTI region 3, which penetrates through the n-type semiconductor region DN, also has a frame-like planar shape. In plan view, the DTI region 3 is included in the n-type semiconductor region DN. In plan view, the frame-shaped DTI region 3 has the function of electrically separating the semiconductor layer EP inside the frame-shaped DTI region 3 from the semiconductor layer EP outside the frame-shaped DTI region 3.

The LDMOSFET 1 is an n-type (n-channel type) LDMOSFET.

The LDMOSFET 1 includes a p-type well region PB, an n-type drift region ND, an n-type drain region DR, the n-type source region SR, a p-type semiconductor region PR, a gate insulating film GF, and the gate electrode GE.

The p-type well region PB, the n-type drift region ND, the n-type drain region DR, the n-type source region SR, and the p-type semiconductor region PR are formed in the semiconductor layer EP1. The gate electrode GE is formed on the semiconductor layer EP1 via the gate insulating film GF. The insulating film IL is formed on the main surface of the semiconductor substrate SUB so as to cover the LDMOSFET 1.

The p-type well region (p-type semiconductor region) PB and the n-type drift region (n-type semiconductor region) ND are formed in the upper portion of the semiconductor layer EP1. The p-type semiconductor layer EP1 is present under the bottom surfaces of the n-type drift region ND and the p-type well region PB. In the gate length direction of the LDMOSFET 1, the n-type drift region ND and the p-type well region PB are adjacent to each other. The gate length direction of the LDMOSFET 1 corresponds to the gate length direction of the gate electrode GE, and the gate width direction of the LDMOSFET 1 corresponds to the gate width direction of the gate electrode GE.

The p-type well region PB is formed so as to surround the n-type source region SR and the p-type semiconductor region PR. The p-type well region PB can function as a back gate. The p-type well region PB can also function as a punch-through stopper, which suppresses the extension of the depletion layer from the drain toward the source in the LDMOSFET 1. Between the n-type source region SR and the n-type drain region DR, the channel of the LDMOSFET 1 is formed in the upper portion of the p-type well region PB located under the gate electrode GE. Hereinafter, a region where the channel of the LDMOSFET 1 is formed will be referred to as a channel formation region.

The n-type source region (n-type semiconductor region) SR and the p-type semiconductor region PR are formed in the p-type well region PB. The n-type source region SR is adjacent to the channel formation region of the LDMOSFET 1. The p-type impurity concentration of the p-type semiconductor region PR is higher than the p-type impurity concentration of the p-type well region PB.

In the case of FIGS. 1 to 3, the p-type semiconductor region PR and the n-type source region SR are adjacent to each other in the gate length direction of the LDMOSFET 1. In this case, the n-type source region SR is arranged between the gate electrode GE and the p-type semiconductor region PR in plan view. In the gate width direction of the LDMOSFET 1, the p-type semiconductor regions PR and the n-type source regions SR may be arranged alternately.

The bottom surface of the p-type semiconductor region PR and the bottom surface of the n-type source region SR are in contact with the p-type well region PB. The upper surface of the p-type semiconductor region PR and the upper surface of the n-type source region SR reach the main surface of the semiconductor substrate SUB. The p-type semiconductor region PR can function as a contact portion of the p-type well region PB.

The n-type drain region (n-type semiconductor region) DR is formed in the n-type drift region ND. The upper surface of the n-type drain region DR reaches the main surface of the semiconductor substrate SUB. The n-type impurity concentration of the n-type drain region DR is higher than the n-type impurity concentration of the n-type drift region ND. The n-type drain region DR and the n-type source region SR are separated from each other in the gate length direction of the LDMOSFET 1.

The gate electrode GE is formed on the main surface of the semiconductor substrate SUB between the n-type source region SR and the n-type drain region DR, via the gate insulating film GF. The gate insulating film GF is made of, for example, a silicon oxide film. The gate electrode GE is made of, for example, a single layer of polycrystalline silicon film (doped polysilicon film) or a laminated film of polycrystalline silicon film and a metal silicide layer.

In plan view, the STI region 2 is arranged between the channel formation region of the LDMOSFET 1 and the n-type drain region DR, and a portion of the gate electrode GE is located on the STI region 2. The n-type drift region ND is present under the STI region 2, which is interposed between the channel formation region of the LDMOSFET 1 and the n-type drain region DR. The bottom surface of the n-type drain region DR is in contact with the n-type drift region ND, and the side surfaces of the n-type drain region DR are in contact with the STI region 2. Accordingly, the n-type drift region ND under the STI region 2 can also function as a conduction path between the channel of the LDMOSFET 1 and the n-type drain region DR.

In FIG. 1, a case is illustrated where the gate insulating film GF is interposed between the STI region 2 and the gate electrode GE; however, the gate insulating film GF may not be interposed between the STI region 2 and the gate electrode GE. Additionally, sidewall spacers made of an insulating film (not illustrated) may be formed on both side surfaces of the gate electrode GE.

A portion of the p-type well region PB is located under the gate electrode GE, and a portion of the n-type drift region ND is located under the gate electrode GE. A P-N junction is formed at the boundary between the p-type well region PB and the n-type drift region ND. The boundary is located under the gate electrode GE and extends in the gate width direction of the LDMOSFET 1.

In plan view, the gate electrode GE is arranged between the n-type source region SR and the n-type drain region DR. When a voltage equal to or higher than a threshold voltage is applied to the gate electrode GE, a channel formed of an n-type inversion layer is formed in the upper portion of the p-type well region PB located under the gate electrode GE. And, the n-type source region SR and the n-type drain region DR are electrically connected to each other via the channel and the n-type drift region ND.

In the gate length direction of the LDMOSFET 1, the n-type drift region ND is interposed between the p-type well region PB and the n-type drain region DR. Accordingly, the n-type drift region ND is present between the channel formation region of the LDMOSFET 1 and the n-type drain region DR. Accordingly, in the gate length direction of the LDMOSFET 1, the channel formation region and the n-type drift region ND are present between the n-type source region SR and the n-type drain region DR, and the channel formation region is located between the n-type source region SR and the n-type drift region ND. Additionally, the p-type semiconductor layer EP1 located under the n-type drift region ND and the p-type well region PB can function as a RESURF region.

Additionally, metal silicide layers (not illustrated) may be formed respectively on the n-type drain region DR, the n-type source region SR, the p-type semiconductor region PR, and the n-type semiconductor region DN1. The metal silicide layers can be formed using the Self-Aligned Silicide (salicide) technique.

Next, the structure on the semiconductor substrate SUB will be described.

As illustrated in FIG. 1, the semiconductor device of the first embodiment further includes a plurality of plugs (contact plugs) PGD, PGN, PGP, and PGS buried in the insulating film IL, and a plurality of wirings M1D, M1N, and M1S formed on the insulating film IL.

The insulating film IL is formed on the main surface of the semiconductor substrate SUB so as to cover the gate electrodes GE. The insulating film IL may be formed of, for example, a laminated film including a silicon nitride film and a silicon oxide film on the silicon nitride film. The upper surface of the insulating film IL is planarized.

A plurality of contact holes (via holes) are formed in the insulating film IL, and a plurality of conductive plugs are formed in the contact holes. The plurality of plugs include the plug PGD, the plug PGN, the plug PGS, and the plug PGP. Each of the plugs PGD, PGN, PGP, and PGS penetrates through the insulating film IL.

The plug PGD is arranged on the n-type drain region DR and is electrically connected to the n-type drain region DR. The plug PGN is arranged on the n-type semiconductor region DN1 and is electrically connected to the n-type semiconductor region DN1. Accordingly, the plug PGN is electrically connected to the n-type semiconductor region DN2 via the n-type semiconductor region DN1, and further, is electrically connected to the n-type buried layer BL via the n-type semiconductor region DN2. In plan view, the plug PGN is surrounded by the DTI region 3 (DTI region 3 penetrating through the n-type semiconductor region DN). In other words, the plug PGN is arranged in a region surrounded by the DTI region 3 in plan view.

The plug PGS is arranged on the n-type source region SR and is electrically connected to the n-type source region SR. The plug PGP is arranged on the p-type semiconductor region PR and is electrically connected to the p-type semiconductor region PR. Accordingly, the plug PGP is electrically connected to the p-type well region PB via the p-type semiconductor region PR.

Additionally, although plugs are also arranged on the gate electrodes GE, the plugs on the gate electrodes GE are not illustrated in the cross-sectional view of FIG. 1.

When the metal silicide layers (not illustrated) are formed on the n-type drain region DR, the n-type source region SR, the p-type semiconductor region PR, and the n-type semiconductor region DN1, each plug is in contact with the metal silicide layer and electrically connected to each of the regions under the metal silicide layer via the metal silicide layer.

A plurality of wirings are formed on the insulating film IL. The plurality of wirings include the source wiring M1S, the drain wiring M1D, and the wiring M1N.

The drain wiring M1D is electrically connected to the n-type drain region DR via the plug PGD. The drain potential is supplied from the drain wiring M1D to the n-type drain region DR via the plug PGD.

The wiring M1N is electrically connected to the n-type semiconductor region DN1 via the plug PGN. The potential supplied from the wiring M1N to the n-type semiconductor region DN1 via the plug PGN is then further supplied to the n-type buried layer BL via the n-type semiconductor region DN2. The n-type semiconductor region DN functions as a power supply region for supplying power to the n-type buried layer BL. The plug PGN functions as a plug for supplying power to the n-type buried layer BL.

The source wiring M1S is electrically connected to the n-type source region SR via the plug PGS and is also electrically connected to the p-type semiconductor region PR via the plug PGP. That is, the source wiring M1S is electrically connected to both the plug PGS, which is arranged on the n-type source region SR, and the plug PGP, which is arranged on the p-type semiconductor region PR.

Due to this, the potential (source potential) supplied from the plug PGS to the n-type source region SR and the potential supplied from the plug PGP to the p-type semiconductor region PR are the same. Accordingly, the source potential is supplied from the plug PGS to the n-type source region SR and then from the plug PGP to the p-type well region PB via the p-type semiconductor region PR.

Although a gate wiring that is electrically connected to the gate electrode GE via a plug is formed on the insulating film IL, the gate wiring is not illustrated in FIG. 1.

The source wiring M1S, the drain wiring M1D, the wiring M1N, and the gate wiring are not connected to each other and are separated from one another.

The illustration and description of the structure above the insulating film IL and the wirings M1D, M1N, and M1S are omitted.

Regarding the LDMOSFET 1, a configuration in which a plurality of unit LDMOSFETs connected in parallel may be adopted. In the case of FIGS. 1 to 3, regarding the LDMOSFET 1, the configuration is such that two unit LDMOSFETs, which share the n-type drain region DR, are connected in parallel. The number of unit LDMOSFETs connected in parallel can be set as needed.

### <Method of Manufacturing Semiconductor Device>

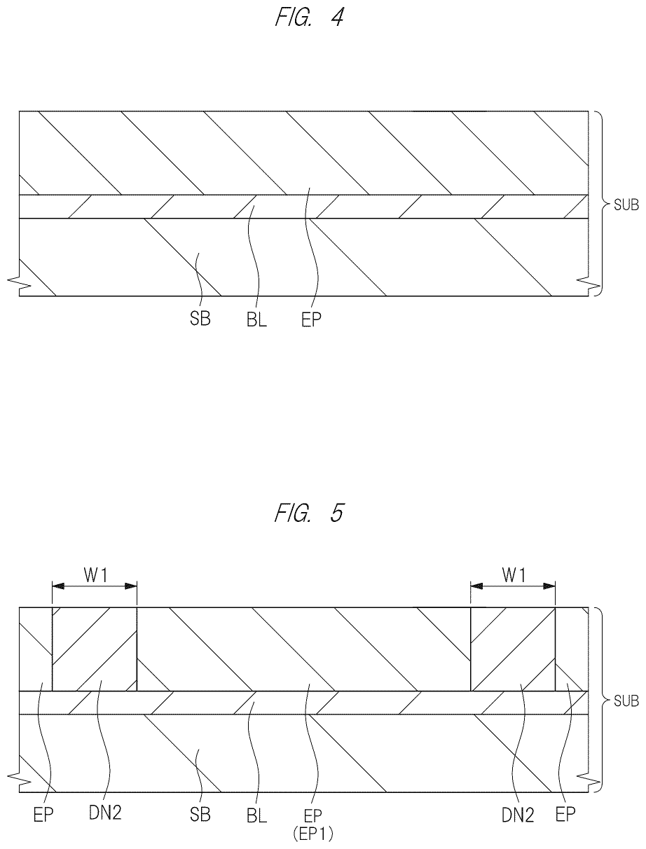

As illustrated in FIG. 4, the semiconductor substrate SUB is prepared that includes the p-type substrate region SB, the n-type buried layer BL on the p-type substrate region SB, and the semiconductor layer EP on the n-type buried layer BL. In FIG. 4, the entire semiconductor layer EP has a p-type conductivity. The thickness of the semiconductor layer EP is, for example, about 3 micrometers or more and 15 micrometers or less.

The n-type buried layer BL can also be formed before forming the semiconductor layer EP. For example, after forming the n-type buried layer BL in the surface layer of the p-type substrate body made of a p-type silicon substrate or the like, by the method of ion implantation, the p-type semiconductor layer EP can be formed on the n-type buried layer BL by the epitaxial growth method. In that case, the region under the n-type buried layer BL in the substrate body corresponds to the p-type substrate region SB.

In the first embodiment, a p-type semiconductor substrate is used as the p-type substrate body. An epitaxial substrate including the p-type semiconductor substrate and a p-type epitaxial semiconductor layer formed on the p-type semiconductor substrate can also be used as the p-type substrate body.

Next, as illustrated in FIG. 5, the n-type semiconductor region DN2 is formed in the semiconductor substrate SUB. For example, after ion implantation of n-type impurities into the p-type semiconductor layer EP, a heat treatment (thermal diffusion treatment) to thermally diffuse the n-type impurities is performed; thereby, forming the n-type semiconductor region DN2. The heat treatment temperature is, for example, about 800° C. or higher and 1200° C. or less. The n-type semiconductor region DN2 is formed so as to reach the n-type buried layer BL from the main surface of the semiconductor substrate SUB. The bottom surface of the n-type semiconductor region DN2 is in contact with the n-type buried layer BL. The width W1 of the n-type semiconductor region DN2 is, for example, about 0.5 micrometers or more and 25 micrometers or less.

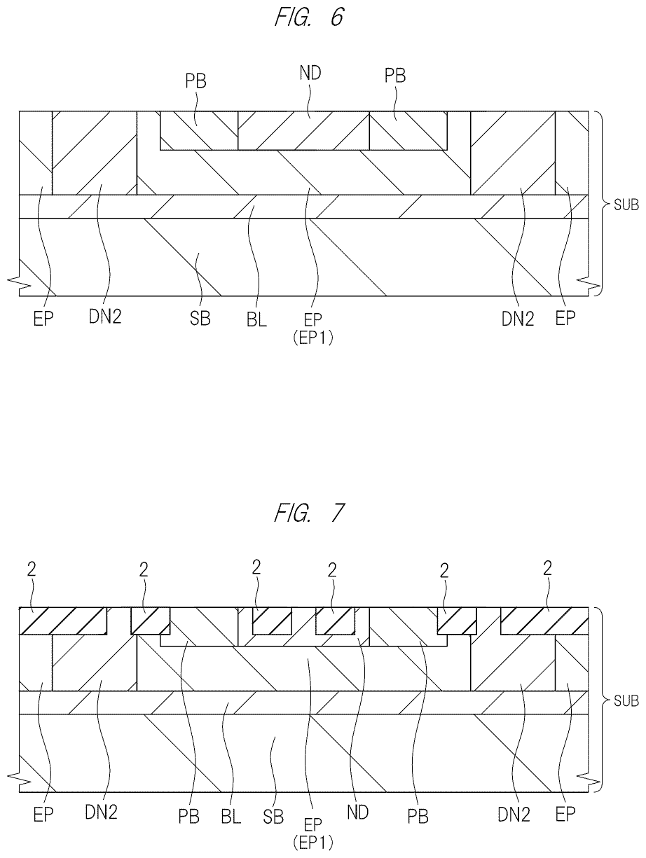

Next, as illustrated in FIG. 6, an n-type drift region ND and a p-type well region PB are each formed in the p-type semiconductor layer EP, by a such a method as ion implantation. The p-type impurity concentration of the p-type well region PB is higher than the p-type impurity concentration of the p-type semiconductor layer EP.

The n-type drift region ND is formed from the main surface of the semiconductor substrate SUB to a predetermined depth. The p-type well region PB is formed from the main surface of the semiconductor substrate SUB to a predetermined depth. Either the n-type drift region ND or the p-type well region PB may be formed first.

Next, as illustrated in FIG. 7, the STI region 2 is formed by the STI method.

After forming a trench on the main surface of the semiconductor substrate SUB, an insulating film made of a silicon oxide film or the like is formed on the main surface of the semiconductor substrate SUB so as to fill the trench. Subsequently, the insulating film arranged outside the trench is removed by such a method as Chemical Mechanical Polishing (CMP) method. Accordingly, the STI region 2 that is made of the insulating film buried in the trench can be formed.

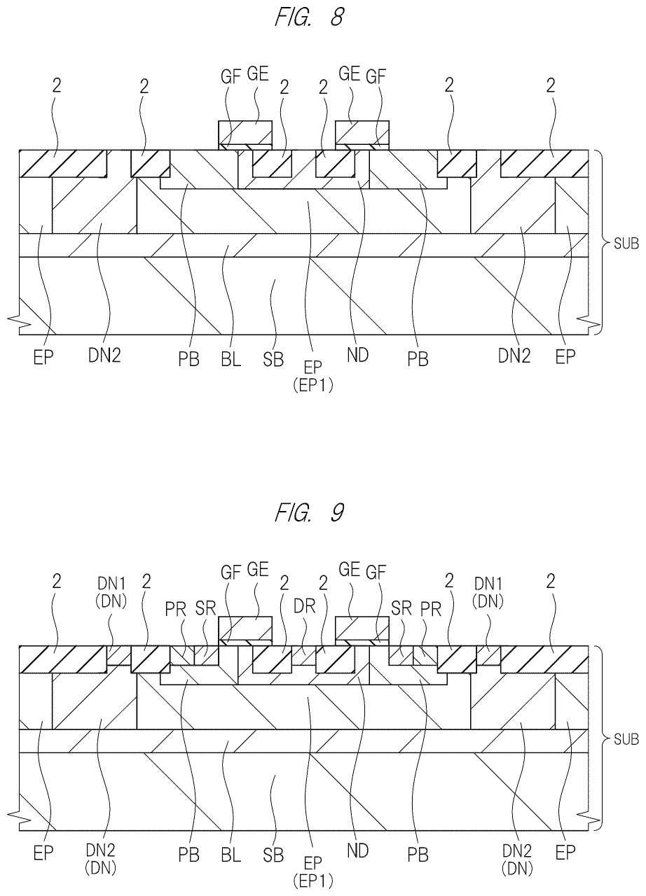

Next, as illustrated in FIG. 8, the gate electrode GE is formed on the main surface of the semiconductor layer EP via the gate insulating film GF. The gate electrode GE is, for example, made of a polycrystalline silicon film. The gate insulating film GF is, for example, made of a silicon oxide film.

Next, as illustrated in FIG. 9, the n-type drain region DR, the n-type source region SR, and the n-type semiconductor region DN1 are formed in the semiconductor layer EP by such a method as ion implantation.

The n-type drain region DR is formed in the n-type drift region ND. The n-type impurity concentration of the n-type drain region DR is higher than the n-type impurity concentration of the n-type drift region ND. The n-type source region SR is formed in the p-type well region PB. The n-type semiconductor region DN1 is formed in the n-type semiconductor region DN2. The n-type impurity concentration of the n-type semiconductor region DN1 is higher than the n-type impurity concentration of the n-type semiconductor region DN2. Whilst, the number of manufacturing steps can be reduced by forming the n-type drain region DR, the n-type source region SR, and the n-type semiconductor region DN1 in the same ion implantation step, the n-type drain region DR, the n-type source region SR, and the n-type semiconductor region DN1 can be formed through separate ion implantation steps.

Next, as illustrated in FIG. 9, the p-type semiconductor region PR is formed in the semiconductor layer EP by such a method as ion implantation. The p-type semiconductor region PR is formed in the p-type well region PB.

In the first embodiment, the p-type semiconductor region PR is formed after the n-type source region SR, the n-type drain region DR, and the n-type semiconductor region DN1 are formed. However, the n-type source region SR, the n-type drain region DR, and the n-type semiconductor region DN1 can also be formed after the p-type semiconductor region PR is formed.

The metal silicide layers (not illustrated) may be formed on the n-type source region SR, the n-type drain region DR, the p-type semiconductor region PR, the n-type semiconductor region DN1, and the gate electrode GE, after the n-type source region SR, the n-type drain region DR, the p-type semiconductor region PR, and the n-type semiconductor region DN1 are formed. The metal silicide layers are formed by Self-Aligned Silicide (Salicide) technique.

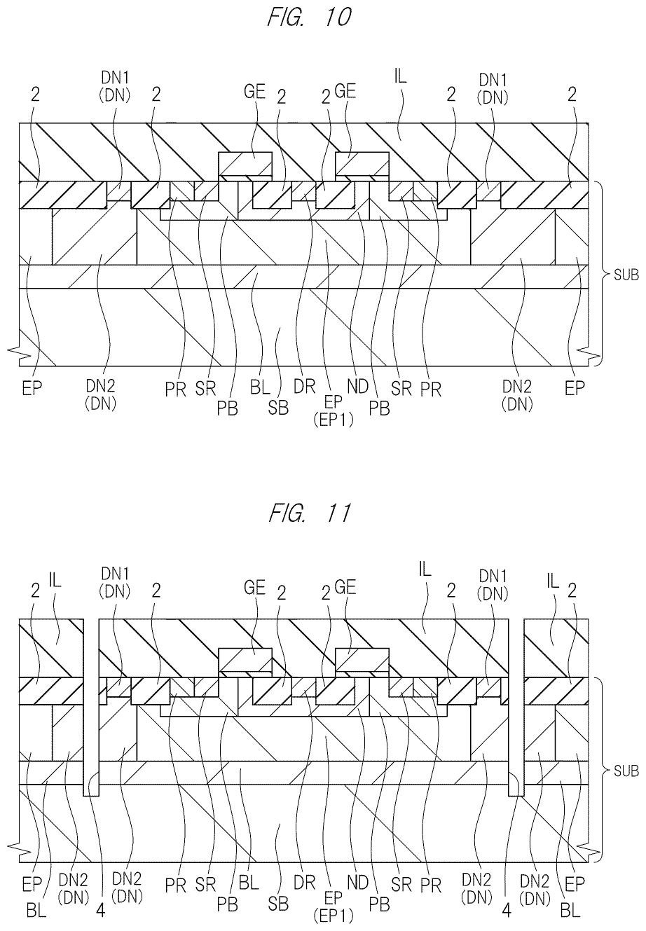

Next, as illustrated in FIG. 10, the insulating film IL is formed on the main surface of the semiconductor substrate SUB so as to cover the gate electrodes GE, by such a method as chemical vapor deposition (CVD). After the insulating film IL is formed, the upper surface of the insulating film IL can also be polished and planarized by such a method as CMP.

Next, as illustrated in FIG. 11, a photoresist pattern (not illustrated) is used as an etching mask to etch the insulating film IL, the STI region 2, and the semiconductor substrate SUB, thereby forming a trench 4. Alternatively, the trench 4 may also be formed by using the photoresist pattern (not illustrated) as an etching mask to etch the insulating film IL, and after removing the photoresist, using the insulating film IL as a mask to etch the semiconductor substrate SUB. The trench 4 penetrates through the insulating film IL, the STI region 2, the semiconductor layer EP, and the n-type buried layer BL, and reaches the p-type substrate region SB.

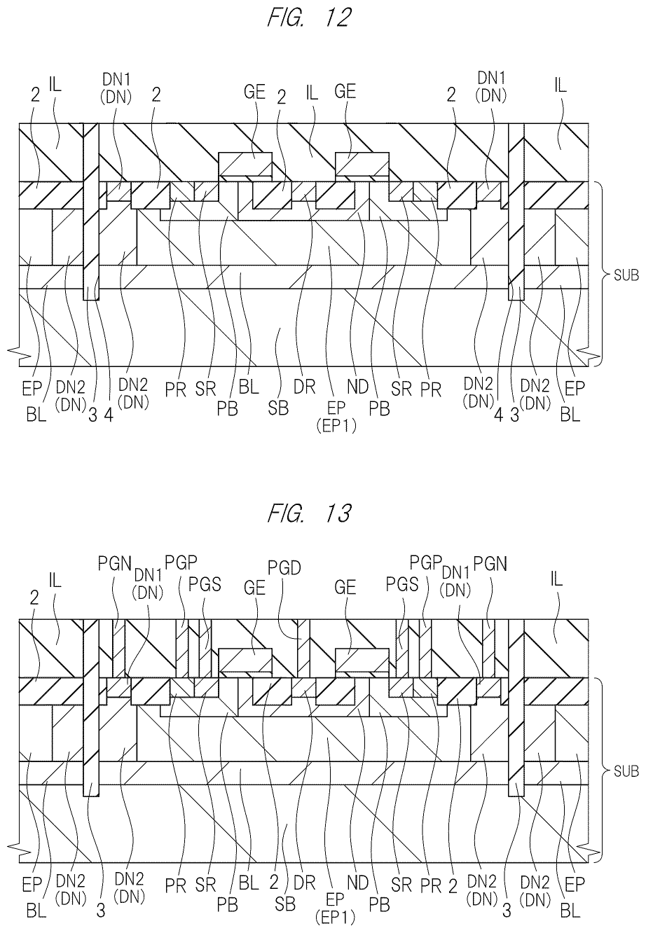

Next, as illustrated in FIG. 12, the DTI region 3 is formed in the trench 4.

After forming the trench 4, an insulating film made of a silicon oxide film or the like is formed on the insulating film IL so as to fill the trench 4. Subsequently, the insulating film arranged outside the trench 4 is removed by such a method as CMP. Accordingly, the DTI region 3 made of an insulating film buried in the trench 4 can be formed. A void may be formed in the DTI region 3. Additionally, in the first embodiment, although a step of removing the insulating film arranged outside the trench 4 by such a method as CMP is performed, this step may be omitted. In that case, the insulating film integrally formed with the DTI region 3 remains on the insulating film IL.

Next, as illustrated in FIG. 13, a plurality of contact holes penetrating through the insulating film IL are formed by etching the insulating film IL using a photoresist pattern (not illustrated) formed on the insulating film IL as an etching mask. Subsequently, a plurality of conductive plugs are each formed in the plurality of contact holes. The plurality of plugs include the plugs PGD, PGN, PGP, and PGS.

For example, a barrier conductor film is formed on the bottom surfaces of the contact holes, the side surfaces of the contact holes, and the upper surface of the insulating film IL. On the barrier conductor film, a main conductor film made of tungsten or the like is formed so as to fill the contact holes. Subsequently, the main conductor film and the barrier conductor film arranged outside the contact holes are removed by such a method as CMP. Accordingly, the plurality of plugs can be formed.

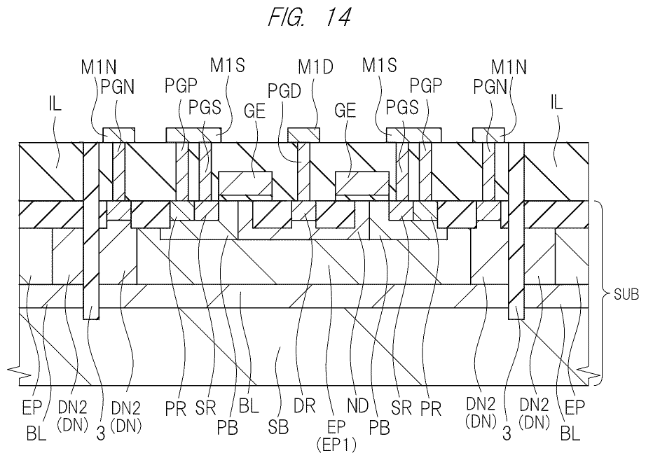

Next, as illustrated in FIG. 14, a plurality of wirings are formed on the insulating film IL. The plurality of wirings include the wirings M1D, M1N, and M1S. For example, a conductive film is formed on the insulating film IL. Subsequently, by patterning the conductive film by photolithography and etching techniques, the plurality of wirings made of the conductive film can be formed. Although the plurality of wirings are preferably aluminum wirings, wirings of other metal materials, such as tungsten wirings, can also be adopted. Additionally, copper wirings formed by damascene technique can also be adopted as the plurality of wirings.

By forming insulating films (not illustrated) of upper layers and wirings (not illustrated) further, a multilayer wiring structure is formed on the semiconductor substrate SUB. The multilayer wiring structure includes a plurality of wiring layers and a plurality of insulating layers. Each of the wirings M1D, M1N, and M1S is a wiring in the lowermost layer among the plurality of wiring layers. The multilayer wiring structure includes a plurality of pads (not illustrated). The plurality of pads include a drain pad electrically connected to the drain wiring M1D, a source pad electrically connected to the source wiring M1S, and a gate pad electrically connected to the gate electrode GE.

Subsequently, the back surface of the semiconductor substrate SUB is ground as necessary, and then the semiconductor substrate SUB is cut (diced) along the scribe region of the semiconductor substrate SUB. Accordingly, a semiconductor device as a semiconductor chip can be manufactured.

### <Background of Examination>

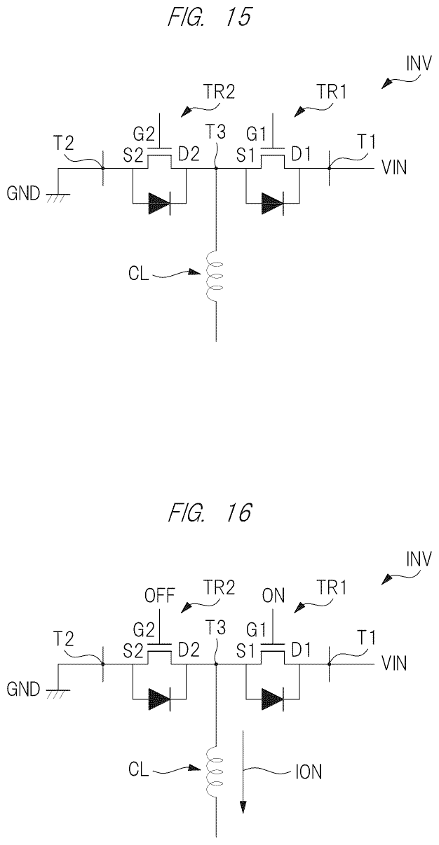

FIG. 15 is a circuit diagram illustrating an inverter circuit INV as an example of a power conversion circuit.

The inverter circuit INV illustrated in FIG. 15 includes a power transistor TR1 and a power transistor TR2 connected in series. Each of the power transistors TR1 and TR2 is a power switching element. The power transistor TR1 is a transistor for the high-side switch (high-potential side switch), and the power transistor TR2 is a transistor for the low-side switch (low-potential side switch). The LDMOSFET 1 can be used as either the power transistor TR1 or the power transistor TR2.

The power transistor TR1 and the power transistor TR2 are connected in series between a terminal T1 and a terminal T2. A drain D1 of the power transistor TR1 is connected to the terminal T1. A source S1 of the power transistor TR1 is connected to a drain D2 of the power transistor TR2. A source S2 of the power transistor TR2 is connected to the terminal T2. A terminal T3 is electrically connected to both the source S1 of the power transistor TR1 and the drain D2 of the power transistor TR2. The power supply potential VIN is supplied to the terminal T1 from a power supply or the like. A reference potential lower than the power supply potential VIN, such as ground potential GND, is supplied to the terminal 2. The terminal T3 is a terminal for output. The terminal T3 is connected to a load. For example, the terminal T3 is connected to a coil CL, which is used in a motor or the like.

A gate G1 of the power transistor TR1 and a gate G2 of the power transistor TR2 are connected to a drive circuit, and a gate voltage is supplied from the drive circuit to the respective gates G1, G2 of the power transistors TR1, TR2. By controlling the gate voltage supplied to the gate G1 of the power transistor TR1 and the gate voltage supplied to the gate G2 of the power transistor TR2, the operation of the power transistors TR1, TR2 can be controlled.

Here, a part of the operation of the inverter circuit INV illustrated in FIG. 15 will be described.

During standby of the inverter circuit INV, the gate voltage of the power transistor TR1 and the gate voltage of the power transistor TR2 are each lower than the respective threshold voltages (for example, 0V). As a result, both the power transistors TR1, TR2 are in the Off state (non-conductive state), and no current flows through the coil CL.

Next, while keeping the gate voltage of the power transistor TR2 lower than the threshold voltage (for example, 0V), a gate voltage equal to or higher than the threshold voltage is supplied to the gate G1 of the power transistor TR1. The power transistor TR1 turns On (conductive state), while the power transistor TR2 turns Off (non-conductive state). FIG. 16 illustrates a circuit diagram representing the state. In the state illustrated in FIG. 16, a current ION flows from the terminal T1 to which the power supply potential VIN is supplied, to the coil CL through the power transistor TR1 and the terminal T3.

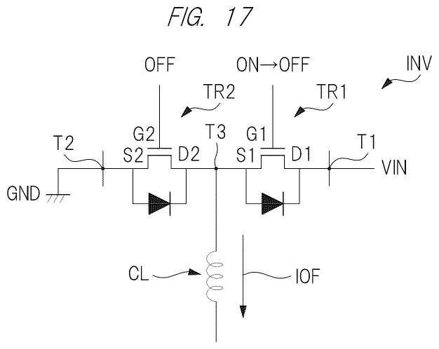

Next, consider the case where, while keeping the gate voltage of the power transistor TR2 lower than the threshold voltage (for example, 0V), the gate voltage of the power transistor TR1 is decreased from a voltage equal to or higher than the threshold voltage to a voltage lower than the threshold voltage (for example, 0V). In this case, the power transistor TR1 is in the On state, and the power transistor TR2 is in the Off state initially, and the power transistors TR1, TR2 both transition to the Off state. At this point, an electromotive force that suppresses the change in the magnetic flux density of the coil CL works, bringing the terminal T3 to a negative potential and resulting in a transient state where a current IOF flows from the terminal T3 to the coil CL. FIG. 17 illustrates the circuit diagram representing the transient state. This transient state (where the terminal T3 is at a negative potential) is resolved over time. That is, the transient state (where the terminal T3 is at a negative potential) temporarily occurs when the power transistor TR1 is in the On state, and the power transistor TR2 is in the Off state initially, and the power transistors TR1, TR2 are both switched to the Off state.

The supply source of the current IOF flowing through the coil CL is configured of a current flowing from the terminal T2 to the terminal T3 through the parasitic diode formed in the power transistor TR2, and a current supplied from the semiconductor substrate in which the power transistor TR2 is formed to the terminal T3 side. That is, in the transient state illustrated in FIG. 17, reflecting the current being supplied from the semiconductor substrate in which the power transistor TR2 is formed to the terminal T3 side, electrons are injected from the drain D2 of the power transistor TR2 into the semiconductor substrate.

The above transient state corresponds to a state where the potential of the source S2 of the power transistor TR2 is at ground potential GND and the potential of the drain D2 of the power transistor TR2 is at a negative potential. When using the LDMOSFET 1 of semiconductor device in the first embodiment as the power transistor TR2, the potential of the drain region (n-type drain region DR) of the LDMOSFET 1 is at a negative potential in the above transient state illustrated in FIG. 17.

When the potential of the drain region (n-type drain region DR) of the LDMOSFET 1 is at a negative potential, electrons are injected from the drain region into the semiconductor substrate SUB. From another perspective, reflecting the injection of electrons from the n-type drain region DR into the semiconductor substrate SUB, holes (positive holes) move from the n-type drain region DR to the plug PGD, and further move to the external terminal T3 of the semiconductor device via the drain wiring M1D and the like, thereby, causing the current IOF to flow from the terminal T3 to the coil CL.

It is necessary to prevent the occurrence of defects in the semiconductor device caused by the injection of electrons from the drain region of the LDMOSFET 1 into the semiconductor substrate SUB when the drain region of the LDMOSFET 1 is at a negative potential.

### Examined Example

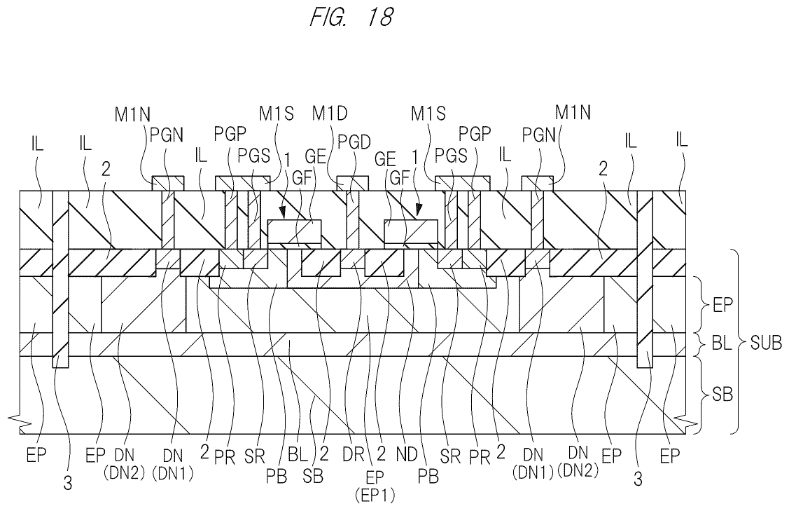

FIG. 18 is a cross-sectional view of the semiconductor device of an examined example considered by the present inventor, illustrating a cross-section corresponding to that in FIG. 1.

A semiconductor device of the examined example illustrated in FIG. 18 differs from the above semiconductor device in FIG. 1 in the following aspects.

In the examined example illustrated in FIG. 18, the DTI region 3 does not penetrating through the n-type semiconductor region DN. In plan view, the DTI region 3 is arranged so as to surround the entire region including the region surrounded by the n-type semiconductor region DN, and the n-type semiconductor region DN.

### Features and Effects of First Embodiment

As described with reference to FIGS. 15 to 17, when using the LDMOSFET 1 as the power transistor TR2 for the low-side switch, the drain region of the LDMOSFET 1 (n-type drain region DR) may be brought to a negative potential. When the n-type drain region DR is at a negative potential, electrons are injected from the n-type drain region DR into the semiconductor substrate SUB. The injected electrons pass through the p-type semiconductor layer EP1 and are injected into the n-type buried layer BL, and further, the electrons are injected from the n-type buried layer BL into the p-type substrate region SB under the n-type buried layer BL. When the potential of the n-type drain region DR is at a negative potential, the potential of the n-type buried layer BL under the p-type semiconductor layer EP1 is also likely to be at a negative potential. As a result, electrons are more likely to be injected from the n-type buried layer BL under the p-type semiconductor layer EP1 into the p-type substrate region SB under the n-type buried layer BL. In a semiconductor region of p-type, holes are the majority carriers, while electrons are the minority carriers. Therefore, when electrons are injected from the n-type buried layer BL into the p-type substrate region SB under the n-type buried layer BL, the injected electrons in the p-type substrate region SB behave as minority carriers. Therefore, the electrons can diffuse in the p-type substrate region SB until the electrons recombine with holes and disappear. Therefore, the electrons injected from the n-type buried layer BL into the p-type substrate region SB have the possibility to move a considerable distance in the p-type substrate region SB. As a result, the electrons that have moved in the p-type substrate region SB may affect the operation of other semiconductor element formed on the semiconductor substrate SUB. This may potentially affect the features of the other semiconductor element, which can lead to a degradation in the performance of the semiconductor device, and thus is undesirable. The other semiconductor element is formed on the semiconductor layer EP other than the semiconductor layer EP1 on which the LDMOSFET 1 is formed, and include, for example, a MOSFET that configures an information processing circuit or an analog circuit.

Therefore, in both the semiconductor device of the first embodiment illustrated in FIG. 1 and the semiconductor device of the examined example illustrated in FIG. 18, the n-type semiconductor region DN is formed in the semiconductor substrate SUB. Accordingly, a fixed potential can be supplied from the plug PGN to the n-type buried layer BL via the n-type semiconductor region DN. As a result, even when the potential of the n-type drain region DR is at a negative potential, the potential of the n-type buried layer BL under the p-type semiconductor layer EP1 remains stable and is fixed to the potential supplied from the plug PGN to the n-type buried layer BL via the n-type semiconductor region DN. Therefore, the negative potential of the n-type drain region DR fluctuating the potential of the n-type buried layer BL under the p-type semiconductor layer EP1 can be prevented. As a result, the phenomenon, in which electrons are injected from the n-type buried layer BL under the p-type semiconductor layer EP1 into the p-type substrate region SB when the potential of the n-type drain region DR is at a negative potential, can be suppressed. The number of electrons injected from the n-type buried layer BL into the p-type substrate region SB can be suppressed; therefore, the possibility that electrons moving in the p-type substrate region SB may affect the operation of the other semiconductor element formed on the semiconductor substrate SUB can be reduced. Therefore, the performance of the semiconductor device can be improved.

However, in the case of the semiconductor device of the examined example illustrated in FIG. 18, in plan view, the n-type semiconductor region DN is arranged so as to surround the LDMOSFET 1, and furthermore, the DTI region 3 is arranged so as to surround the entire region including the region surrounded by the n-type semiconductor region DN and the n-type semiconductor region DN. Accordingly, in the case of the semiconductor device illustrated in the examined example of FIG. 18, it is necessary to secure an area to arrange the n-type semiconductor region DN around the LDMOSFET 1, and also to secure an area to arrange the DTI region 3 around the n-type semiconductor region DN, on the main surface of the semiconductor substrate SUB, leading to enlargement in the total area of the semiconductor device.

In contrast, in the case of the semiconductor device of the first embodiment illustrated in FIGS. 1 to 3, the DTI region 3 is formed so as to penetrate through the n-type semiconductor region DN. Therefore, in plan view, the n-type semiconductor region DN is arranged so as to surround the LDMOSFET 1, and the DTI region 3 is arranged in the n-type semiconductor region DN. In the case of the first embodiment, although it is necessary to secure the area to arrange the n-type semiconductor region DN around the LDMOSFET 1, it is not necessary to secure the area to arrange the DTI region 3 around the n-type semiconductor region DN at the main surface of the semiconductor substrate SUB. Accordingly, compared to the semiconductor device in the examined example illustrated in FIG. 18, in the case of the semiconductor device of the first embodiment illustrated in FIGS. 1 to 3, the total area of the semiconductor device can be reduced. Therefore, the semiconductor device can be downsized.

The plug PGN is arranged on the n-type semiconductor region DN1 and is electrically connected to the n-type semiconductor region DN1. The potential supplied from the wiring M1N to the plug PGN is supplied from the plug PGN to the n-type semiconductor region DN1, then, supplied to the n-type semiconductor region DN2 via the n-type semiconductor region DN1, and then, further supplied to the n-type buried layer BL via the n-type semiconductor region DN2. The potential supplied from the plug PGN to the n-type buried layer BL via the n-type semiconductor region DN is a fixed potential, and preferably either ground potential (zero volts) or a positive potential. That is, the potential supplied from the plug PGN to the n-type buried layer BL via the n-type semiconductor region DN is preferably a fixed potential that is not a negative potential. Accordingly, the phenomenon in which electrons are injected from the n-type buried layer BL into the p-type substrate region SB can be accurately suppressed.

When using the LDMOSFET 1 as a power transistor TR2 for a low-side switch, the potential supplied from the plug PGN to the n-type buried layer BL via the n-type semiconductor region DN can be set to the same potential (ground potential) as the source potential supplied from the plug PGS to the n-type source region SR. Accordingly, the circuit configuration of the semiconductor device can be simplified.

When using the LDMOSFET 1 as a power transistor TR1 for a high-side switch, the potential supplied from the plug PGN to the n-type buried layer BL via the n-type semiconductor region DN can be set to the same potential (positive power supply potential) as the drain potential supplied to the n-type drain region DR from the plug PGD. Accordingly, the circuit configuration of the semiconductor device can be simplified.

### Second Embodiment

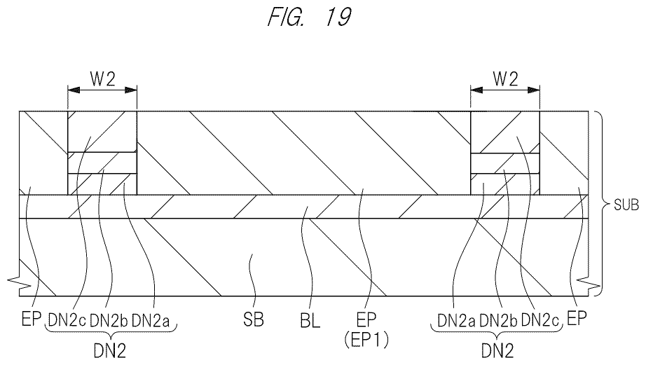

FIG. 19 is a cross-sectional view of a main portion of the semiconductor device during a manufacturing step according to a second embodiment.

Similarly to the first embodiment, after preparing the semiconductor substrate SUB as illustrated in FIG. 4, in the second embodiment, an n-type semiconductor region DN2 is formed in the semiconductor substrate SUB, as illustrated in FIG. 19.

In the second embodiment, the n-type semiconductor region DN2 is formed through a plurality of ion implantation steps. The implantation energies for the plurality of ion implantation steps to form the n-type semiconductor region DN2 are different from each other.

By performing ion implantation to form an n-type semiconductor region DN2a, ion implantation to form an n-type semiconductor region DN2b, and ion implantation to form an n-type semiconductor region DN2c, an n-type semiconductor region DN2 including the n-type semiconductor region DN2a, the n-type semiconductor region DN2b, and the n-type semiconductor region DN2c can be formed.

The ion implantation to form the n-type semiconductor region DN2a, the ion implantation to form the n-type semiconductor region DN2b, and the ion implantation to form the n-type semiconductor region DN2c are performed using a common photoresist pattern (not illustrated) formed on the main surface of the semiconductor substrate SUB as an ion implantation blocking mask. The implantation energy for the ion implantation to form the n-type semiconductor region DN2a is greater than the implantation energy for the ion implantation to form the n-type semiconductor region DN2b, and is also greater than the implantation energy for the ion implantation to form the n-type semiconductor region DN2c. The implantation energy for the ion implantation to form the n-type semiconductor region DN2b is greater than the implantation energy for the ion implantation to form the n-type semiconductor region DN2c.

Due to this, in plan view, the n-type semiconductor region DN2a, the n-type semiconductor region DN2b, and the n-type semiconductor region DN2c overlap each other, the n-type semiconductor region DN2b is formed under the n-type semiconductor region DN2c, and the n-type semiconductor region DN2a is formed under the n-type semiconductor region DN2b. As a result, the n-type semiconductor region DN2, which includes the n-type semiconductor region DN2a, the n-type semiconductor region DN2b, and the n-type semiconductor region DN2c, is formed so as to reach the n-type buried layer BL from the main surface of the semiconductor substrate SUB.

The subsequent steps in the second embodiment are the same as those in the first embodiment described above.

In the first embodiment described above, the n-type semiconductor region DN2 is formed by a single ion implantation followed by a thermal diffusion treatment. Meanwhile, in the second embodiment, the n-type semiconductor region DN2 is formed by a plurality of ion implantation steps with different implantation energies from one another. Therefore, in the case of the second embodiment, the thermal diffusion length of the n-type impurities when forming the n-type semiconductor region DN2 can be reduced compared to the first embodiment described above. For example, in the second embodiment, in a case where, either no thermal diffusion treatment is performed or the thermal diffusion treatment is performed after the n-type semiconductor region DN2, the temperature of the thermal diffusion treatment can be lowered compared to the temperature used in the thermal diffusion treatment of the first embodiment described above.

Therefore, the width W2 of the n-type semiconductor region DN2 in the second embodiment (see FIG. 19) can be made smaller than the width W1 of the n-type semiconductor region DN2 in the first embodiment (see FIG. 5). For example, the width W2 can be set to about 60% to 70% of the width W1. As a result, the area of the n-type semiconductor region DN, which is arranged around the LDMOSFET 1 at the main surface of the semiconductor substrate SUB can be reduced; therefore, the total area of the semiconductor device can be further reduced. Therefore, further downsizing of the semiconductor device can be achieved.

### Third Embodiment

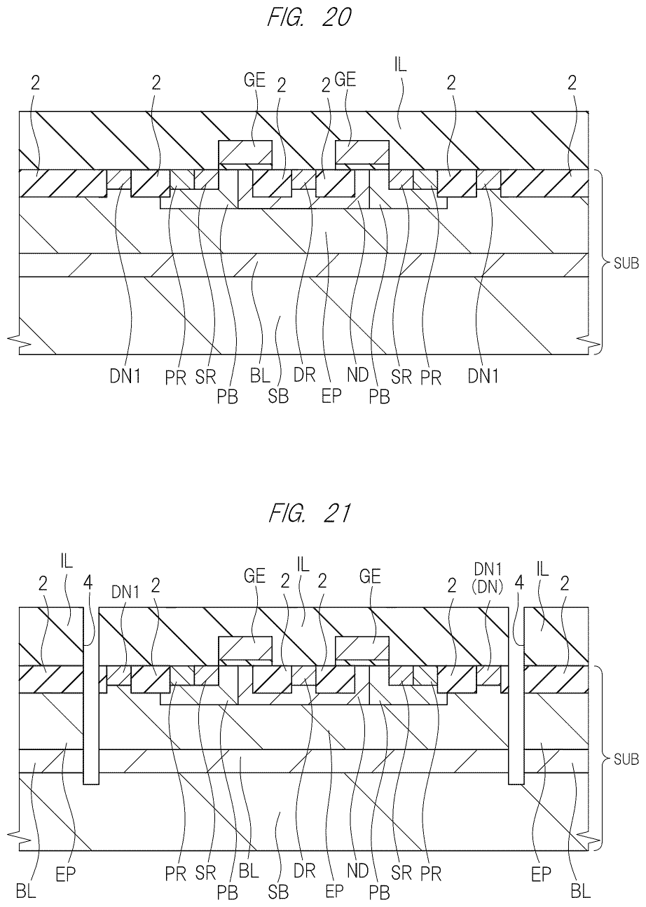

FIGS. 20 to 24 are cross-sectional views of a main portion of a semiconductor device during manufacturing steps in the third embodiment. FIG. 20 corresponds to FIG. 10 and illustrates the stage at which the insulating film IL has been formed.

In the third embodiment, the step of forming the n-type semiconductor region DN2 illustrated in FIG. 5 is not performed. Other than that step, the remaining steps are similarly performed as in the first embodiment, resulting in obtaining the structure of FIG. 20 corresponding to FIG. 10. Due to this, in FIG. 20, the n-type semiconductor region DN2 is not formed in the semiconductor substrate SUB.

After forming the insulating film IL, a photoresist pattern (not illustrated) is used as an etching mask, as illustrated in FIG. 21. And, by etching the insulating film IL, the STI region 2, and the semiconductor substrate SUB, a trench 4 is formed. Alternatively, the photoresist pattern (not illustrated) is used as an etching mask to etch the insulating film IL. After removing the photoresist, the insulating film IL is used as a mask to etch the semiconductor substrate SUB, thereby forming the trench 4. The trench 4 penetrates through the insulating film IL, the STI region 2, the semiconductor layer EP, and the n-type buried layer BL, and reaches the p-type substrate region SB.

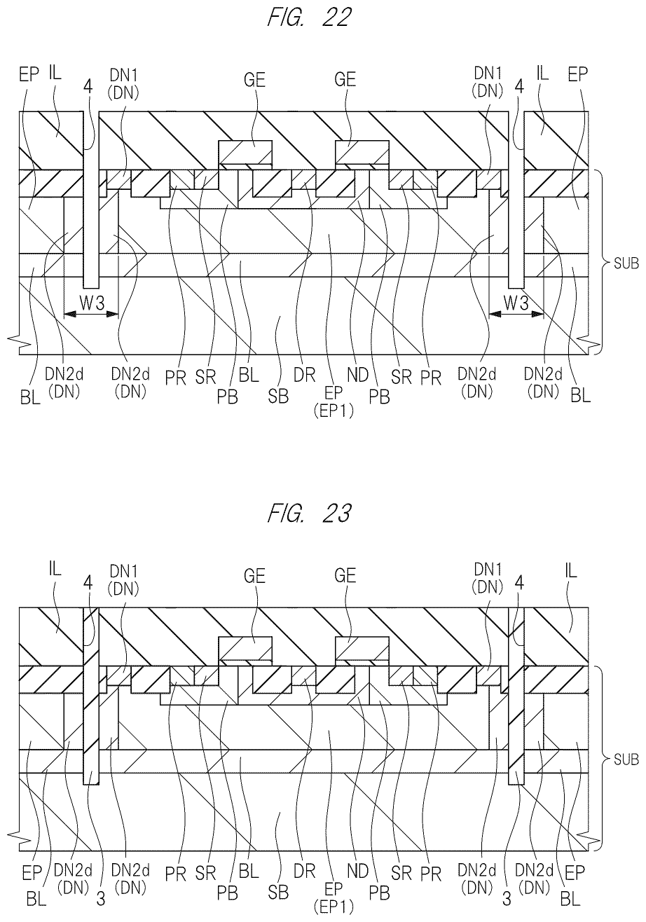

Next, as illustrated in FIG. 22, an n-type semiconductor region DN2d is formed in the semiconductor substrate SUB by performing oblique ion implantation of n-type impurities. The n-type semiconductor region DN2d is formed by implanting n-type impurities into the semiconductor layer EP from a side surface of the trench 4. Accordingly, the n-type semiconductor region DN2d is formed in contact with the side surface of the trench 4. Reflecting this, the trench 4 penetrates through the n-type semiconductor region DN2d.

The conditions for the oblique ion implantation are set according to factors such as the thickness of the insulating film IL and the width of the trench 4. For example, the implantation angle for the oblique ion implantation is about 4 degrees or more and 10 degrees or less. Note that the implantation angle for the oblique ion implantation corresponds to the angle of gradient relative to the normal direction of the main surface of the semiconductor substrate SUB.

The n-type semiconductor region DN2d corresponds to the n-type semiconductor region DN2 described above. The upper surface of the n-type semiconductor region DN2d is in contact with the bottom surface of the n-type semiconductor region DN1, and the bottom surface of the n-type semiconductor region DN2d is in contact with the n-type buried layer BL. Due to this, the n-type semiconductor region DN1 is electrically connected to the n-type buried layer BL via the n-type semiconductor region DN2d. In the third embodiment, the n-type semiconductor region DN2 is formed by the n-type semiconductor region DN2d and the n-type semiconductor region DN1. The n-type impurity concentration of the n-type semiconductor region DN1 is higher than the n-type impurity concentration of the n-type semiconductor region DN2d.

Next, as illustrated in FIG. 23, the DTI region 3 is formed in the trench 4.

After forming the n-type semiconductor region DN2d, an insulating film made of a silicon oxide film or the like is formed on the insulating film IL so as to fill the trench 4. Subsequently, the insulating film arranged outside the trench 4 is removed by such a method as CMP. Accordingly, the DTI region 3, which is made of the insulating film buried in the trench 4, can be formed. A void may be formed in the DTI region 3. Additionally, although, in the third embodiment, a step of removing the insulating film arranged outside the trench 4 by such a method as CMP is performed, this step may not be performed. In that case, the insulating film, which is formed integrally with the DTI region 3, remains on the insulating film IL.

The trench 4 penetrates through the STI region 2, the n-type semiconductor region DN2d, and the n-type buried layer BL; therefore, the DTI region 3 buried in the trench 4 also penetrates through the STI region 2, the n-type semiconductor region DN2d, and the n-type buried layer BL.

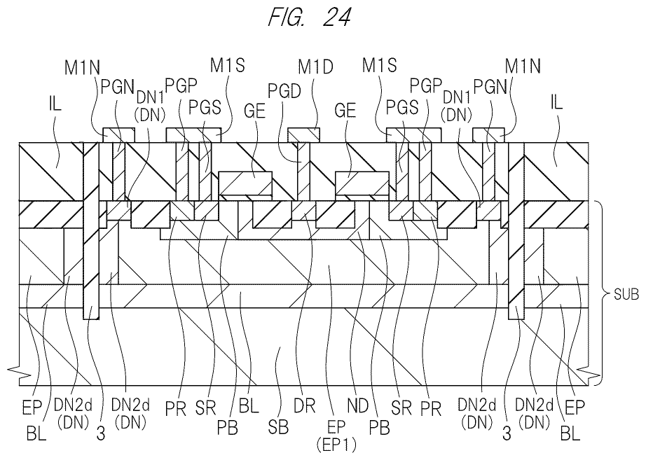

Next, as illustrated in FIG. 24, in the third embodiment, a plurality of contact holes are formed in the insulating film IL, a plurality of plugs are formed in the contact holes, and a plurality of wirings are formed on the insulating film IL, as in the first embodiment above.

The width W3 of the n-type semiconductor region DN2d (see FIG. 22) can be made smaller than the width W1 of the n-type semiconductor region DN2 in the first embodiment (see FIG. 5) and the width W2 of the n-type semiconductor region DN2 in the second embodiment (see FIG. 19). As a result, the area of the n-type semiconductor region DN, which is arranged around the LDMOSFET 1 at the main surface of the semiconductor substrate SUB can be reduced; therefore, the total area of the semiconductor device can be further reduced. Therefore, further downsizing of the semiconductor device can be achieved.

### Fourth Embodiment

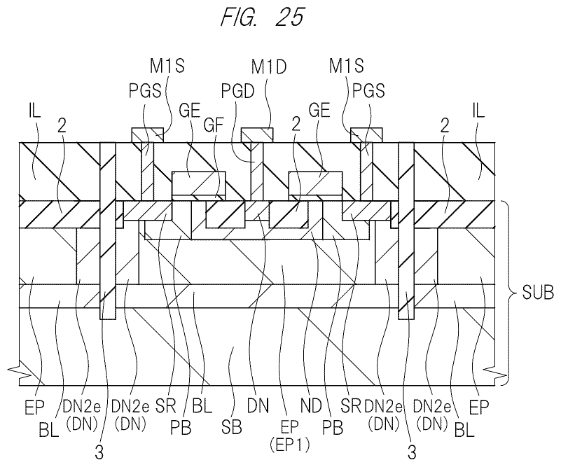

FIG. 25 is a cross-sectional view of a main portion of a semiconductor device according to a fourth embodiment.

In the fourth embodiment, the n-type semiconductor region DN1 described above is not formed, and instead of the n-type semiconductor region DN2, an n-type semiconductor region DN2e is formed. In the fourth embodiment, the n-type semiconductor region DN2e can be formed by the method similar to the method of forming the n-type semiconductor region DN2d in the third embodiment.

The n-type semiconductor region DN2e is formed so as to be in contact with the n-type source region SR. The upper surface of the n-type semiconductor region DN2e is in contact with the bottom surface of the n-type source region SR and the bottom surface of the STI region 2, while the bottom surface of the n-type semiconductor region DN2e is in contact with the n-type buried layer BL. Due to this, the n-type source region SR is electrically connected to the n-type buried layer BL via the n-type semiconductor region DN2e. In the fourth embodiment, the n-type semiconductor region DN2 is formed by the n-type semiconductor region DN2e. The n-type impurity concentration of the n-type source region SR is higher than the n-type impurity concentration of the n-type semiconductor region DN2e. The DTI region 3 penetrates through the insulating film IL, the STI region 2, the n-type semiconductor region DN2e, and the n-type buried layer BL.

In the case of FIG. 25, the n-type source regions SR and the p-type semiconductor regions PR are alternately arranged in the gate width direction of the gate electrode GE. FIG. 25 is a cross-sectional view across the n-type source region SR; therefore, while the n-type source regions SR are illustrated in FIG. 25, the p-type semiconductor regions PR is not illustrated in FIG. 25.

In the fourth embodiment, the above plug PGN and the above wiring M1N are not formed. In the fourth embodiment, the source wiring M1S is electrically connected to the n-type source region SR via the plug PGS and is further electrically connected to the n-type buried layer BL via the n-type semiconductor region DN2e. Due to this, the potential (source potential) supplied from the plug PGS to the n-type source region SR is further supplied to the n-type buried layer BL via the n-type semiconductor region DN2e. Additionally, the source wiring M1S is electrically connected to the p-type semiconductor region PR via the plug PGP and is further electrically connected to the p-type well region PB.

Accordingly, the potential (source potential) supplied from the source wiring M1S to the n-type source region SR via the plug PGS is further supplied to the n-type buried layer BL via the n-type semiconductor region DN2e. Additionally, the same potential as the potential (source potential) supplied from the source wiring M1S to the n-type source region SR via the plug PGS is supplied from the source wiring M1S to the p-type semiconductor region PR via the plug PGP, and is further supplied from the p-type semiconductor region PR to the p-type well region PB.

Other configuration of the semiconductor device in the fourth embodiment is similar to that of the semiconductor device in the third embodiment.

Additionally, in the fourth embodiment, the n-type semiconductor region DN2e is formed by the method similar to the method of forming the n-type semiconductor region DN2d in the above third embodiment, however, the n-type semiconductor region DN2e can also be formed by the method similar to the method of forming the n-type semiconductor region DN2 in the first embodiment or the second embodiment.

In the fourth embodiment, the n-type semiconductor region DN can be arranged in contact with the n-type source region SR; therefore, the total area of the semiconductor device can be further reduced compared to the above first, second, and third embodiments. Therefore, further downsizing of the semiconductor device can be achieved.

In the case of the fourth embodiment, the potential of the n-type buried layer BL is fixed to the source potential supplied from the plug PGS to the n-type source region SR.

In the cases of the first, second, and third embodiments, the potential of the n-type buried layer BL is fixed to the potential supplied from the plug PGN to the n-type semiconductor region DN. Due to this, in the cases of the first, second, and third embodiments, the potential of the n-type buried layer BL can be controlled independently of the source potential supplied from the plug PGS to the n-type source region SR.

### Fifth Embodiment

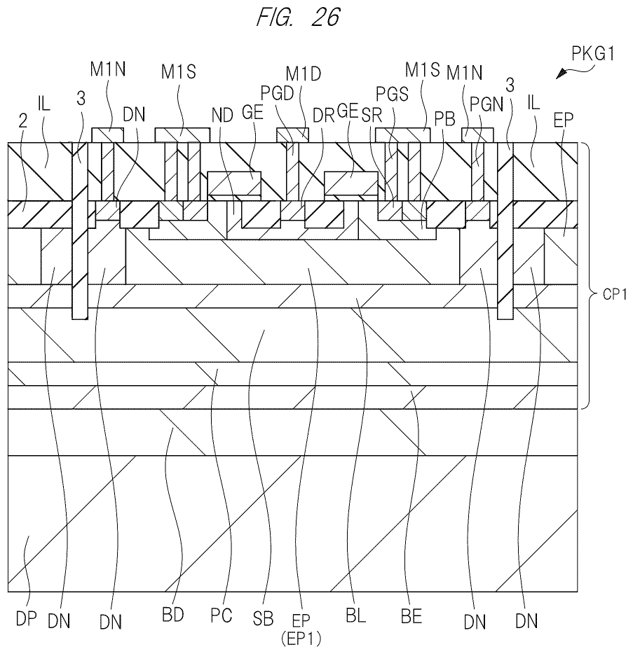

FIG. 26 is a cross-sectional view of a main portion of a semiconductor package (semiconductor device) PKG1 in which a semiconductor device (semiconductor chip) CP1 of the fifth embodiment is used.

As illustrated in FIG. 26, the semiconductor package PKG1 includes a die pad DP and a semiconductor device CP1, which is arranged on the die pad DP via a conductive bonding material BD. The semiconductor package PKG1 further includes a plurality of conductive members (not illustrated) that electrically connect the plurality of pads (not illustrated) to a plurality of leads (not illustrated) of the semiconductor device CP1. As conductive members, for example, bonding wires or metal plates can be used. The semiconductor package PKG1 further includes a resin sealing portion (not illustrated) that seals the semiconductor device CP1, the die pad DP, the plurality of leads, and the plurality of conductive members.

The die pad DP is a chip mounting portion for mounting the semiconductor device CP1 and is conductive. The die pad DP is made of a metallic material such as copper. The bonding material BD is, for example, made of solder, a silver paste, or a conductive die attach film (DAF).

The configuration of the semiconductor device CP1 will be described below.

The semiconductor device CP1 of the fifth embodiment includes a back surface electrode BE formed on the back surface of the semiconductor substrate SUB. And, in the p-type substrate region SB, a p-type semiconductor region PC is formed so as to be in contact with the back surface electrode BE. The back surface electrode BE is electrically connected to the p-type semiconductor region PC. The p-type impurity concentration of the p-type semiconductor region PC is higher than the p-type impurity concentration of the p-type substrate region SB. The p-type semiconductor region PC is formed in a layered manner so as to be in contact with the back surface electrode BE. The p-type semiconductor region PC and the n-type buried layer BL are separated from each other, and the p-type substrate region SB with p-type impurity concentration lower than that of the p-type semiconductor region PC is interposed between the p-type semiconductor region PC and the n-type buried layer BL.

Other configurations of the semiconductor device CP1 of the fifth embodiment are similar to those of the semiconductor devices of any of the first, second, third, and fourth embodiments.

The manufacturing steps of the semiconductor device CP1 of the fifth embodiment will be described below.

Similarly to any of the first, second, third, and fourth embodiments, after performing up to the step of forming a multilayer wiring structure on the semiconductor substrate SUB, the back surface of the semiconductor substrate SUB is ground as necessary.

Next, in the fifth embodiment, the p-type semiconductor region PC is formed in the p-type substrate region SB from the back surface of the semiconductor substrate SUB to a predetermined depth by the ion implantation method.

Next, the back surface electrode BE is formed on the back surface of the semiconductor substrate SUB by such a method as sputtering. The back surface electrode BE is formed so as to be in contact with the p-type semiconductor region PC. The back surface electrode BE is electrically connected to the p-type semiconductor region PC.

After that, the semiconductor substrate SUB is cut (diced) along the scribe region of the semiconductor substrate SUB. As a result, the semiconductor device CP1, as a semiconductor chip, can be obtained.

The manufacturing process of the semiconductor package PKG1 will be briefly explained below.

The semiconductor device CP1 is arranged on the die pad DP via the conductive bonding material BD. The back surface electrode BE of the semiconductor device CP1 is electrically connected to the die pad DP via a conductive bonding material BD. Next, the plurality of pads (not illustrated) and the plurality of leads (not illustrated) of the semiconductor device CP1 are electrically connected to each other via the plurality of conductive members (not illustrated). Next, the resin sealing portion (not illustrated) that seals the semiconductor device CP1, the die pad DP, the plurality of leads, and the plurality of conductive members is formed. Thereafter, if necessary, a lead frame cutting step or the like is performed.

In the semiconductor package PKG1 of the fifth embodiment, the die pad DP is electrically connected to the back surface electrode BE via the conductive bonding material BD, and is further electrically connected to the p-type semiconductor region PC via the back surface electrode BE. The die pad DP of the semiconductor package PKG1 is connected to ground potential. Due to this, ground potential is supplied from the die pad DP to the back surface electrode BE via the conductive bonding material BD, and further, ground potential is supplied to the p-type semiconductor region PC via the back surface electrode BE.

For example, when mounting the semiconductor package PKG1 onto a wiring board, the die pad DP of the semiconductor package PKG1 is electrically connected to the ground terminal of the wiring board via solder or the like. Accordingly, ground potential can be supplied from the ground terminal of the wiring board to the die pad DP of the semiconductor package PKG1 via solder or the like, and further ground potential can be supplied from the die pad DP to the back surface electrode BE via the conductive bonding material BD.

As described above, when electrons are injected from the n-type buried layer BL into the p-type substrate region SB, the electrons can move by diffusion in the p-type substrate region SB until the electrons recombine with holes and disappear, since the electrons injected into the p-type substrate region SB behave as minority carriers. In this case, there is concern that the electrons moving in the p-type substrate region SB may affect the operation of other semiconductor element formed on the semiconductor substrate SUB.

In the fifth embodiment, ground potential is supplied from the die pad DP to the p-type semiconductor region PC via the conductive bonding material BD and the back surface electrode BE; therefore, holes can be supplied from the back surface electrode BE to the p-type semiconductor region PC. Accordingly, the electrons injected from the n-type buried layer BL into the p-type substrate region SB move into the p-type semiconductor region PC, thereby facilitating the phenomenon of recombination with holes in the p-type semiconductor region PC. As a result, the number of electrons moving in the p-type substrate region SB can be suppressed; therefore, the possibility for the electrons to affect the operation of the other semiconductor element formed on the semiconductor substrate SUB can be reduced. Therefore, the performance of the semiconductor device can be further improved.

In the semiconductor device CP1 of the fifth embodiment, the DTI region 3 is formed so as to penetrate through the n-type semiconductor region DN. Accordingly, as described in the first embodiment, the total area of the semiconductor device CP1 can be reduced, and the semiconductor device CP1 can be downsized.

In the semiconductor device CP1 of the fifth embodiment, it is also possible for the DTI region 3 to be arranged so as to surround the entire region in which the semiconductor layer EP1 and the n-type semiconductor region DN are combined in plan view, without penetrating through the n-type semiconductor region DN. Holes can also be supplied from the back surface electrode BE to the p-type semiconductor region PC in this case too, accordingly, the electrons injected from the n-type buried layer BL into the p-type substrate region SB move into the p-type semiconductor region PC, leading to facilitating the phenomenon of recombination with holes in the p-type semiconductor region PC. As a result, the number of electrons moving in the p-type substrate region SB can be suppressed; therefore, the possibility for the electrons to affect the operation of the other semiconductor element formed on the semiconductor substrate SUB can be reduced. Therefore, the performance of the semiconductor device can be improved.

### Sixth Embodiment

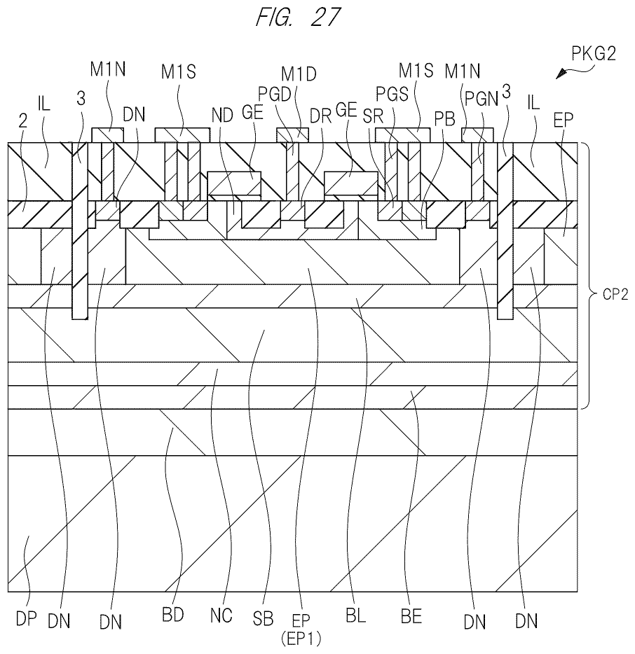

FIG. 27 is a cross-sectional view of a main portion of a semiconductor package (semiconductor device) PKG2 in which a semiconductor device (semiconductor chip) CP2 of a sixth embodiment is used.

As illustrated in FIG. 27, the semiconductor package PKG2 includes a die pad DP and a semiconductor device CP2, which is arranged on the die pad DP via a conductive bonding material BD. The semiconductor package PKG2 further includes a plurality of conductive members (not illustrated) that electrically connect a plurality of pads (not illustrated) to a plurality of leads (not illustrated) of the semiconductor device CP2. The semiconductor package PKG2 further includes a resin sealing portion (not illustrated) that seals the semiconductor device CP2, the die pad DP, the plurality of leads, and the plurality of conductive members.

The configuration of the semiconductor device CP2 will be described below.

The semiconductor device CP2 of the sixth embodiment includes a back surface electrode BE formed on the back surface of the semiconductor substrate SUB. And, in the p-type substrate region SB, an n-type semiconductor region NC is formed so as to be in contact with the back surface electrode BE. The back surface electrode BE is electrically connected to the n-type semiconductor region NC. The n-type semiconductor region NC is formed in a layered manner so as to be in contact with the back surface electrode BE. The n-type semiconductor region NC and the n-type buried layer BL are separated from each other, and the p-type substrate region SB is interposed between the n-type semiconductor region NC and the n-type buried layer BL.

Other configurations of the semiconductor device CP2 of the sixth embodiment are similar to those of the semiconductor devices of any of the first, second, third, and fourth embodiments.

The manufacturing steps of the semiconductor device CP2 in the sixth embodiment are the same as the manufacturing steps of the semiconductor device CP1 in the fifth embodiment, except that the n-type semiconductor region NC is formed instead of the p-type semiconductor region PC.

The manufacturing steps of the semiconductor package PKG2 in the sixth embodiment are the same as the manufacturing steps of the semiconductor package PKG1 in the fifth embodiment, except that the semiconductor device CP2 is used instead of the semiconductor device CP1.

In the semiconductor package PKG2 of the sixth embodiment, the die pad DP is electrically connected to the back surface electrode BE via the conductive bonding material BD, and is further electrically connected to the n-type semiconductor region NC via the back surface electrode BE. The die pad DP of the semiconductor package PKG2 is connected to a positive fixed potential. Due to this, the positive fixed potential is supplied from the die pad DP to the back surface electrode BE via the conductive bonding material BD, and further, the positive fixed potential is supplied to the n-type semiconductor region NC via the back surface electrode BE. As the positive fixed potential, for example, a positive power supply potential can be used.

For example, when mounting the semiconductor package PKG2 onto a wiring board, the die pad DP of the semiconductor package PKG2 is electrically connected to a terminal of the wiring board via solder or the like. Accordingly, the positive fixed potential can be supplied from the terminal of the wiring board to the die pad DP of the semiconductor package PKG2 via solder or the like, and further the positive fixed potential can be supplied from the die pad DP to the back surface electrode BE via the conductive bonding material BD.

The positive fixed potential supplied to the back surface electrode BE of the semiconductor device CP2 is preferably equal to or higher than the highest potential among the source potential supplied from the plug PGS to the n-type source region SR, the drain potential supplied from the plug PGD to the n-type drain region DR, and the potential supplied from the plug PGN to the n-type semiconductor region DN.

As described above, when electrons are injected from the n-type buried layer BL into the p-type substrate region SB, the electrons can move by diffusion in the p-type substrate region SB until the electrons recombine with holes and disappear, since the electrons injected into the p-type substrate region SB behave as minority carriers. In this case, there is concern that the electrons moving in the p-type substrate region SB may affect the operation of other semiconductor element formed on the semiconductor substrate SUB.

In the sixth embodiment, the positive fixed potential is supplied from the die pad DP to the n-type semiconductor region NC via the conductive bonding material BD and the back surface electrode BE. Due to this, the electrons injected from the n-type buried layer BL into the p-type substrate region SB move to the n-type semiconductor region NC and further to the back surface electrode BE from the n-type semiconductor region NC. The electrons that have moved from the n-type semiconductor region NC to the back surface electrode BE can move to the die pad DP via the conductive bonding material BD, and further move from the die pad DP to terminals or the like on the wiring board on which semiconductor package PKG2 is mounted.

By supplying the positive fixed potential to the back surface electrode BE of the semiconductor device CP2, a portion of the electrons injected from the n-type buried layer BL into the p-type substrate region SB can be directed to the die pad DP via the n-type semiconductor region NC, the back surface electrode BE, and the conductive bonding material BD. As a result, the number of electrons moving in the p-type substrate region SB can be suppressed; therefore, the possibility for the electrons to affect the operation of the other semiconductor element formed on the semiconductor substrate SUB can be reduced. Therefore, the performance of the semiconductor device can be further improved.

In the semiconductor device CP2 of the sixth embodiment, the DTI region 3 is formed so as to penetrate through the n-type semiconductor region DN. Accordingly, as described in the first embodiment, the total area of the semiconductor device CP2 can be reduced, and the semiconductor device CP2 can be downsized.

In the semiconductor device CP2 of the sixth embodiment, it is also possible for the DTI region 3 to be arranged such that it does not penetrate through the n-type semiconductor region DN but instead surrounds the entire region in which the semiconductor layer EP1 and the n-type semiconductor region DN are combined in plan view. In that case too, the positive fixed potential can also be supplied to the back surface electrode BE of the semiconductor device CP2, a portion of the electrons injected from the n-type buried layer BL into the p-type substrate region SB can be directed to the die pad DP via the n-type semiconductor region NC, the back surface electrode BE, and the conductive bonding material BD. As a result, the number of electrons moving in the p-type substrate region SB can be suppressed; therefore, the possibility for the electrons to affect the operation of the other semiconductor element formed on the semiconductor substrate SUB can be reduced. Therefore, the performance of the semiconductor device can be improved.

In the foregoing, the invention made by the inventors of the present application has been concretely described on the basis of the embodiments. However, it is needless to say that the present invention is not limited to the foregoing embodiments, and various modifications and alterations can be made in the scope of the present invention.

What is claimed is:

1. A semiconductor device comprising:
a semiconductor substrate having a main surface and a back surface opposite the main surface;
a transistor formed on the main surface of the semiconductor substrate;
an insulating film formed on the main surface of the semiconductor substrate so as to cover the transistor; and
a first contact plug buried in the insulating film,
wherein the semiconductor substrate includes:
a substrate region of a first conductivity type;
a buried layer of a second conductivity type opposite the first conductivity type, formed on the substrate region; and
a semiconductor layer of the first conductivity type formed on the buried layer; and
a first semiconductor region of the second conductivity type formed in the semiconductor layer so as to surround the transistor in plan view and so as to reach the buried layer from the main surface,
wherein the first contact plug is arranged on the first semiconductor region and is electrically connected to the first semiconductor region, and
wherein the semiconductor device further comprises an insulating region that penetrates through the first semiconductor region and the buried layer and reaches the substrate region.

2. The semiconductor device according to claim 1,
wherein the insulating region is formed so as to surround the transistor in plan view.

3. The semiconductor device according to claim 2,
wherein the insulating region penetrates through the insulating film, the first semiconductor region, and the buried layer, and reaches the substrate region.

4. The semiconductor device according to claim 3, further comprising:
an STI region formed at the main surface of the semiconductor substrate,
wherein the insulating region is a DTI region, and
wherein a bottom surface of the DTI region is deeper than a bottom surface of the STI region.

5. The semiconductor device according to claim 1,
wherein the transistor is a power switching element.

6. The semiconductor device according to claim 5,
wherein the transistor is a transistor of the second conductivity type.

7. The semiconductor device according to claim 5,
wherein the first conductivity type is a p-type,
wherein the second conductivity type is an n-type, and
wherein the transistor is an n-type MOSFET.

8. The semiconductor device according to claim 7,
wherein the transistor includes:
a gate electrode formed on the semiconductor layer via a gate insulating film;
a source region formed in the semiconductor layer; and
a drain region formed in the semiconductor layer, and
wherein the source region and the drain region are surrounded by the first semiconductor region in plan view.

9. The semiconductor device according to claim 1,
wherein, in plan view, the first contact plug is surrounded by the insulating region, and
wherein a first fixed potential is supplied from the first contact plug to the buried layer via the first semiconductor region.

10. The semiconductor device according to claim 9,
wherein the first conductivity type is a p-type,
wherein the second conductivity type is an n-type, and
wherein the first fixed potential is a ground potential or a positive potential.

11. The semiconductor device according to claim 1, further comprising:
a second semiconductor region of the first conductivity type formed in the substrate region, and reaching the back surface; and
a back surface electrode formed on the back surface of the semiconductor substrate,
wherein impurity concentration of the second semiconductor region of the first conductivity type is higher than impurity concentration of the substrate region of the first conductivity type,
wherein the semiconductor device is arranged on a die pad via a conductive bonding material such that the back surface electrode faces the die pad via the bonding material,
wherein the back surface electrode is electrically connected to the die pad via the bonding material, and
wherein a ground potential is supplied from the die pad to the back surface electrode via the bonding material.

12. The semiconductor device according to claim 1, further comprising:
a third semiconductor region of the second conductivity type formed in the substrate region, and reaching the back surface; and
a back surface electrode formed on the back surface of the semiconductor substrate,
wherein the semiconductor device is arranged on a die pad via a conductive bonding material such that the back surface electrode faces the die pad via the bonding material,
wherein the back surface electrode is electrically connected to the die pad via the bonding material, and
wherein a positive second fixed potential is supplied from the die pad to the back surface electrode via the bonding material.

13. A method of manufacturing a semiconductor device, the method comprising:
(a) preparing a semiconductor substrate including:
a substrate region of a first conductivity type;
a buried layer of a second conductivity type opposite the first conductivity type, formed on the substrate region; and
a semiconductor layer of the first conductivity type formed on the buried layer;
(b) forming a first semiconductor region of the second conductivity type in the semiconductor layer so as to reach the buried layer from a main surface of the semiconductor substrate;
(c) after the (b), forming a transistor on the main surface of the semiconductor substrate;
(d) after the (c), forming an insulating film on the main surface of the semiconductor substrate so as to cover the transistor;
(e) after the (d), forming an insulating region that penetrates through the insulating film, the first semiconductor region, and the buried layer and reaches the substrate region; and
(f) after the (e), forming a first contact plug buried in the insulating film,
wherein the transistor is surrounded by the first semiconductor region in plan view, and
wherein the first contact plug is electrically connected to the first semiconductor region.

14. The method according to claim 13,
wherein, in the (b), the first semiconductor region is formed by single ion implantation and a heat treatment after the ion implantation.

15. The method according to claim 13,
wherein, in the (b), the first semiconductor region is formed by a plurality of ion implantations, and
wherein implantation energies of the plurality of ion implantations are different from each other.

16. A method of manufacturing a semiconductor device, the method comprising:
(a) preparing a semiconductor substrate including:
a substrate region of a first conductivity type;
a buried layer of a second conductivity type opposite the first conductivity type, formed on the substrate region; and
a semiconductor layer of the first conductivity type formed on the buried layer;
(b) forming a transistor on the main surface of the semiconductor substrate;
(c) after the (b), forming an insulating film on the main surface of the semiconductor substrate so as to cover the transistor;
(d) after the (c), forming a trench that penetrates through the insulating film, the semiconductor layer, and the buried layer, and reaches the substrate region;
(e) after the (d), forming a first semiconductor region of the second conductivity type, that reaches the buried layer, by injecting impurities of the second conductivity type into the semiconductor layer from a side surface of the trench by oblique ion implantation;
(f) after the (e), forming an insulating region buried in the trench; and
(g) after the (f), forming a first contact plug buried in the insulating film,
wherein the transistor is surrounded by the first semiconductor region in plan view, and
wherein the first contact plug is electrically connected to the first semiconductor region.
